(19) United States
(12) Patent Application Publication
(10) Pub. No.: US 2026/0223623 A1
(43) Pub. Date: Jul. 30, 2026

(54) SUBSTRATE PROCESSING APPARATUS AND SUBSTRATE PROCESSING METHOD

(71) Applicant: Tokyo Electron Limited, Tokyo (JP)

(72) Inventor: Gentaro GOSHI, Koshi City (JP)

(21) Appl. No.: 19/456,155

(22) Filed: Jan. 22, 2026

(30) Foreign Application Priority Data
Jan. 30, 2025 (JP) 2025-014079

(51) Int. Cl. H10P 72/00; H10P 72/30

(52) U.S. Cl. CPC H10P 72/0408; H10P 72/0414; H10P 72/0436; H10P 72/3412

(57) ABSTRACT

A substrate processing apparatus comprises a drying device configured to dry a processing surface of at least one substrate, a holder configured to hold the at least one substrate dried by the drying device, and an irradiator configured to irradiate the at least one substrate held by the holder with infrared light.

### CROSS-REFERENCE TO RELATED APPLICATION

This application is based upon and claims the benefit of priority from Japanese Patent Application No. 2025-014079, filed on Jan. 30, 2025, the entire contents of which are incorporated herein by reference.

### TECHNICAL FIELD

The present disclosure relates to a substrate processing apparatus and a substrate processing method.

### BACKGROUND

Patent Document 1 discloses that a fine groove pattern of 100 nm or less generates a phenomenon called capillary condensation due to the influence of capillary force acting in a minute space. Patent Document 2 discloses a technique for suppressing moisture absorption and capillary condensation caused by a fine pattern after a supercritical drying process by hydrophobizing a surface of the fine pattern of a substrate after the supercritical drying process.

### PRIOR ART DOCUMENTS

### Patent Documents

Patent Document 1: Japanese Patent Registration No. 6503606
Patent Document 2: Japanese Laid-Open Patent Publication No. 2024-087769

### SUMMARY

According to one embodiment of the present disclosure, a substrate processing apparatus comprises a drying device configured to dry a processing surface of at least one substrate, a holder configured to hold the at least one substrate dried by the drying device, and an irradiator configured to irradiate the at least one substrate held by the holder with infrared light.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic view illustrating a substrate processing apparatus according to a first embodiment.

FIG. 2 is a cross-sectional view illustrating an example of a liquid processing device.

FIG. 3 is a perspective view illustrating an example of a drying device.

FIG. 4 is a diagram illustrating an example of a deliverer.

FIG. 5 is a diagram illustrating another example of the deliverer.

FIG. 6 is a schematic plan view illustrating a substrate processing apparatus according to a second embodiment.

FIG. 7 is a flowchart illustrating a substrate processing method according to the second embodiment.

### DETAILED DESCRIPTION

Hereinafter, non-limitative exemplary embodiments of the present disclosure will be described with reference to the accompanying drawings. In all the accompanying drawings, the same or corresponding members or components will be denoted by the same or corresponding reference numerals, and redundant descriptions thereof will be omitted. In this specification, an X axis, a Y axis, and a Z axis are orthogonal to each other. The X axis and Y axis extend horizontally, while the Z axis extends vertically.

### First Embodiment

### Substrate Processing Apparatus

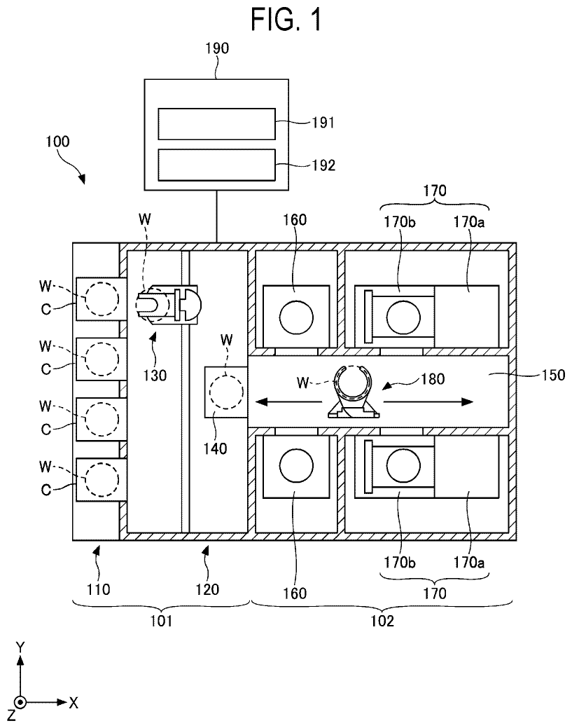

A substrate processing apparatus 100 according to a first embodiment will now be described with reference to FIG. 1. FIG. 1 is a schematic view illustrating the substrate processing apparatus 100 according to the first embodiment.

The substrate processing apparatus 100 is configured as an apparatus for processing substrates W one by one. The substrate processing apparatus 100 includes a loading/unloading station 101, a processing station 102, and a control circuit 190.

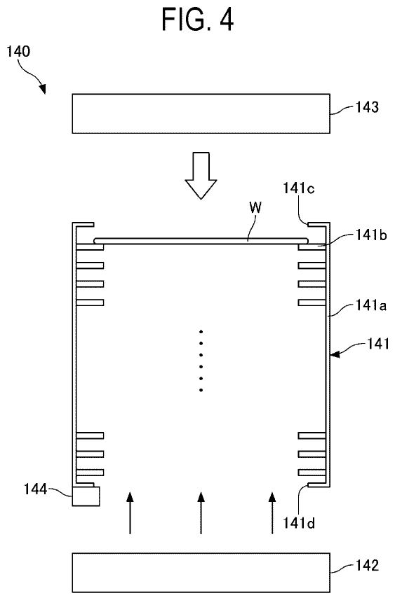

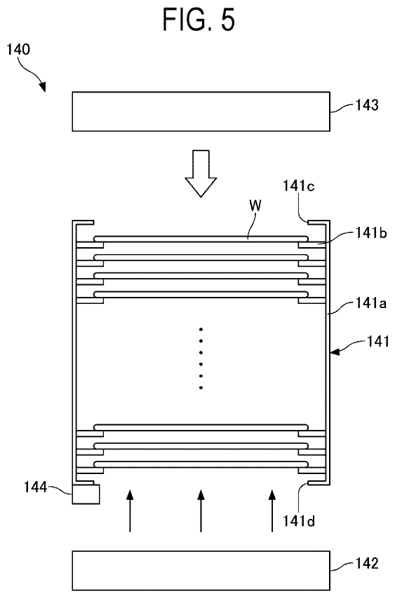

The loading/unloading station 101 includes a stage 110 and a transferor 120. The stage 110 is configured to place a plurality of carriers C thereon. A plurality of substrates W is accommodated in each carrier C in a horizontal posture. Each carrier C is, for example, a front opening unified pod (FOUP). The substrate W is, for example, a semiconductor wafer. A processing surface of the substrate W may be any surface of the substrate W. An upper surface of the substrate W may be the processing surface, or both upper and lower surfaces of the substrate W may be the processing surface. In the present embodiment, the upper surface of the substrate W is the processing surface in which a fine pattern is formed. The transferor 120 is provided with a first transfer mechanism 130 and a deliverer 140. The first transfer mechanism 130 transfers the substrate W between the carrier C placed on the stage 110 and the deliverer 140. The deliverer 140 temporarily stores the substrate W. Details of a configuration example of the deliverer 140 will be described later (see FIGS. 4 and 5).

The processing station 102 is provided to be adjacent to the loading/unloading station 101 in a positive side of the X axis. The processing station 102 includes a transfer path 150, a liquid processing device 160, a drying device 170, and a second transfer mechanism 180. One set of the liquid processing device 160 and the drying device 170 is provided on a positive side of the transfer path 150 in the Y axis. Two or more sets of the liquid processing devices 160 and the drying devices 170 may be provided in multiple stages in a height direction (along the Z axis) on the positive side of the transfer path 150 in the Y axis. One set of the liquid processing device 160 and the drying device 170 is provided on a negative side of the transfer path 150 in the Y axis. Two or more sets of the liquid processing devices 160 and the drying devices 170 may be provided in multiple stages on the negative side of the transfer path 150 in the Y axis. In the processing station 102, liquid processing by the liquid processing device 160 and drying processing by the drying device 170 are performed in this order on each substrate W.

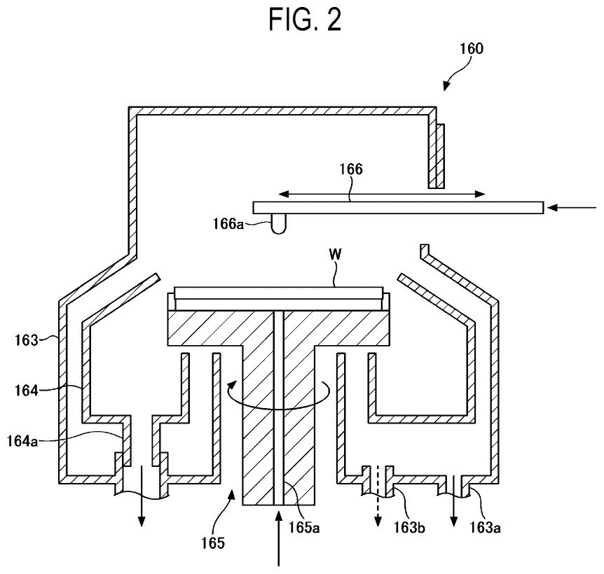

The liquid processing device 160 performs liquid processing by supplying liquid to the processing surface of the substrate W. Examples of the liquid processing may include processing for performing wet etching on the processing surface of the substrate W, cleaning processing for cleaning the processing surface of the substrate W, and liquid film formation processing for forming a liquid film on the processing surface of the substrate W. In the present embodiment, the processing surface of the substrate W after the liquid processing by the liquid processing device 160 has hydrophilicity. For example, the processing surface exhibits hydrophilicity by performing the liquid processing (the cleaning processing) on the processing surface of the substrate W using SC1 (a mixed solution of deionized water, ammonium hydroxide solution, and hydrogen peroxide solution). Details of a configuration example of the liquid processing device 160 will be described later (see FIG. 2).

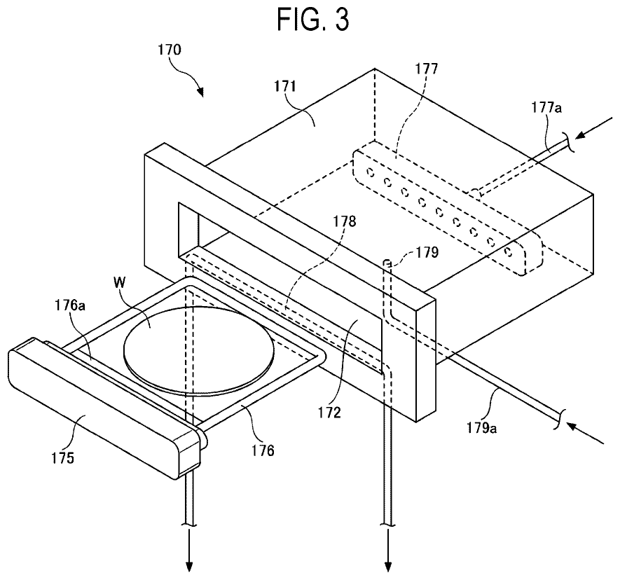

The drying device 170 performs supercritical drying processing that dries, using a supercritical fluid, the substrate W having the processing surface on which the fine pattern is formed. The drying device 170 supplies the supercritical fluid to the processing surface of the substrate W on which a liquid film has been formed to replace the liquid film on the processing surface with the supercritical fluid. Thereafter, the drying device 170 dries the substrate W by vaporizing and scattering the supercritical fluid on the processing surface. The drying device 170 includes a drying processing area 170a and a delivery area 170b. Supercritical drying processing is performed in the drying processing area 170a. In the delivery area 170b, the substrate W is received from the second transfer mechanism 180 and the substrate W is delivered to the second transfer mechanism 180. Details of a configuration example of the drying device 170 will be described later (see FIG. 3).

In this embodiment, after the above-described liquid processing and drying processing are performed on each substrate W, the substrate W is accommodated in the carrier C in which humidity has been lowered by an air conditioner (not shown) for the carrier C. As a result, moisture absorption in the substrate W (especially in the fine pattern) after the drying processing while the substrate W is being accommodated in the carrier C is reduced, thereby suppressing collapse of the fine pattern.

A configuration for maintaining an interior of each carrier C at a low humidity and a method therefor are not limited. For example, a purge device (not shown) functioning as an air conditioner may be installed in the stage 110, and the carrier C may be connected to the purge device when the carrier C is placed on the stage 110. In this case, by supplying a low-humidity purge gas (an inert gas such as a nitrogen gas) from the purge device to the interior of the carrier C, purging the interior of the carrier C is purged with the low-humidity purge gas so that the interior of the carrier C may be adjusted to have a low-humidity atmosphere.

The control circuit 190 is, for example, a computer. The control circuit 190 includes a calculator 191 such as a central processing unit (CPU) and a storage 192 such as a memory. The storage 192 stores programs for controlling various types of processing executed by the substrate processing apparatus 100. The control circuit 190 controls the operation of the substrate processing apparatus 100 by causing the calculator 191 to execute the programs stored in the storage 192. The programs may be stored in a non-transitory computer-readable storage medium (device) such as a hard disk, a compact disc, a magneto-optical disc, a memory card, or a non-volatile memory, and may be installed in the computer from the storage medium.

The control circuit 190 includes one or more electronic circuits such as a CPU, a field programmable gate array (FPGA), or an application specific integrated circuit (ASIC) and executes various control operations described herein by executing instruction codes stored in the memory or by being designed as a circuit for a special purpose.

### Liquid Processing Apparatus

An example of the liquid processing device 160 included in the substrate processing apparatus 100 will now be described with reference to FIG. 2. FIG. 2 is a cross-sectional view illustrating an example of the liquid processing device 160.

The liquid processing device 160 is configured as, for example, a single-substrate type cleaning device for cleaning the substrates W one by one by spin cleaning. In the liquid processing device 160, the substrate W is held substantially horizontally by a substrate holding mechanism 165 in a processing space inside an outer chamber 163 and is rotated about a vertical axis together with the substrate holding mechanism 165. A chemical liquid nozzle 166a provided at a tip portion of a nozzle arm 166 is positioned above the substrate W. A chemical liquid or a rinse liquid is discharged from the chemical liquid nozzle 166a toward an upper surface (the processing surface) of the substrate W, thereby performing the cleaning processing on the upper surface of the substrate W.

A chemical liquid supply path 165a is formed to penetrate the substrate holding mechanism 165. The cleaning processing on a lower surface of the substrate W is performed by a chemical liquid or a rinse liquid discharged from the chemical liquid supply path 165a toward the lower surface of the substrate W held by the substrate holding mechanism 165.

In the cleaning processing, the liquid processing device 160 first supplies, for example, SC1, which is an alkaline chemical liquid, to the substrate W to remove particles or organic contaminants. Next, the liquid processing device 160 supplies deionized water, which is the rinse liquid, to the substrate W to perform the rinse cleaning. Thereafter, the liquid processing device 160 supplies dilute hydrofluoric acid (DHF), which is an acidic chemical liquid, to the substrate W to remove a native oxide film, and subsequently, supplies the deionized water to the substrate W to perform the rinse cleaning.

The various chemical liquids supplied to the substrate W are received by the outer chamber 163 and an inner cup 164 inside the outer chamber 163 and are discharged from a drainage port 163a formed in a bottom portion of the outer chamber 163 and a drainage port 164a formed in a bottom portion of the inner cup 164. An internal atmosphere of the outer chamber 163 is exhausted from an exhaust port 163b formed in a bottom portion of the outer chamber 163.

The liquid processing device 160 performs liquid film formation processing that forms a liquid film on the upper and lower surfaces of the substrate W after the rinse cleaning in the cleaning processing described above. Specifically, liquid of isopropyl alcohol (IPA) is supplied to the upper and lower surfaces of the substrate W while the substrate W is rotated together with the substrate holding mechanism 165. Thus, the deionized water remaining on the both surfaces of the substrate W is replaced with IPA. Thereafter, the rotation of the substrate holding mechanism 165 is gently stopped.

In a state in which the liquid film of IPA is formed on the upper surface of the substrate W (that is, a liquid collection state), the substrate W is delivered to the second transfer mechanism 180 (see FIG. 1) from the substrate holding mechanism 165 via a transfer mechanism (not shown) and is unloaded from the liquid processing device 160. The liquid film collected on the substrate W in this manner prevents the fine pattern on the upper surface of the substrate W from collapsing due to evaporation (vaporization) of the liquid on the upper surface during the transfer of the substrate W from the liquid processing device 160 to the drying device 170 and during loading of the substrate W into the drying device 170.

### Drying Device

An example of the drying device 170 included in the substrate processing apparatus 100 will now be described with reference to FIG. 3. FIG. 3 is a perspective view illustrating an example of the drying device 170.

The drying device 170 is configured as, for example, a supercritical drying device that dries the substrates W by bringing each substrate W having a liquid film formed on the surface thereof into contact with a supercritical fluid one by one. The drying device 170 includes a container main body 171. The container main body 171 has an opening 172. The drying device 170 includes a cover member 175. The cover member 175 is movably provided to support a holding plate 176 and to open and close the opening 172. The holding plate 176 horizontally holds the substrate W to be processed. The holding plate 176, along with the substrate W, passes through the opening 172 according to the opening/closing operation of the cover member 175 and is disposed in an inner space of the container main body 171 (see the drying processing area 170a in FIG. 1) or outside the container main body 171 (see the delivery area 170b in FIG. 1). When the cover member 175 is disposed at a closed position, the opening 172 is hermetically sealed by the cover member 175, and the inner space of the container main body 171 is sealed and isolated from the outside.

The container main body 171 is, for example, a container whose interior is formed as a processing space capable of accommodating the substrate W having a diameter of 300 mm. A fluid supply header 177 is provided on one end side of the interior of the container main body 171. The fluid supply header 177 is configured as a block body provided with a plurality of openings. It is desirable that the openings of the fluid supply header 177 be located at a position slightly higher than the upper surface of the substrate W accommodated in a processing space while being held by the holding plate 176. A fluid discharge header 178 is provided on the other end side of the container main body 171. The fluid discharge header 178 is configured as a pipe provided with a plurality of openings.

The fluid supply header 177 and the fluid discharge header 178 are not limited to the example shown in FIG. 3. For example, the fluid discharge header 178 may be configured as a block body, and the fluid supply header 177 may be configured as a pipe.

When viewed from below, the holding plate 176 covers substantially the entire area of the lower surface of the substrate W. The holding plate 176 has an opening 176a at an end portion on the side of the cover member 175. A processing fluid in a space above the holding plate 176 passes through the opening 176a and is guided to the fluid discharge header 178.

The fluid supply header 177 is connected to a first supply line 177a that supplies the supercritical fluid to the fluid supply header 177. The fluid supply header 177 supplies the supercritical fluid to the processing space in a horizontal direction. The “horizontal direction” is a direction in which the flat upper and lower surfaces of the substrate W, which is held by the holding plate 176 and accommodated in the processing space, extend.

A fluid in the interior of the container main body 171 is discharged to the outside of the container main body 171 via the fluid discharge header 178. The fluid discharged through the fluid discharge header 178 includes not only the processing fluid supplied into the container main body 171 via the fluid supply header 177, but also liquid components (for example, IPA) dissolved in the processing fluid from the surface of the substrate W.

A fluid supply nozzle 179 that supplies the supercritical fluid into the container main body 171 is provided at a bottom portion of the container main body 171. The fluid supply nozzle 179 is configured as an opening formed in a bottom wall of the container main body 171 and is connected to a second supply line 179a that supplies the supercritical fluid to the fluid supply nozzle 179. The fluid supply nozzle 179 is positioned below (for example, directly below) a central portion of the substrate W and supplies the processing fluid into the processing space toward the central portion of the substrate W (for example, upward in the vertical direction).

### Deliverer

An example of the deliverer 140 included in the substrate processing apparatus 100 will now be described with reference to FIGS. 4 and 5. FIGS. 4 and 5 are diagrams illustrating an example of the deliverer 140. FIG. 4 illustrates a state in which one substrate W is temporarily stored in the deliverer 140, and FIG. 5 illustrates a state in which a plurality of substrates Wis temporarily stored in the deliverer 140.

The deliverer 140 temporarily stores the substrates W. The substrates W include both substrates prior to being processed in the liquid processing device 160 and the drying device 170, and substrates after being processed in the liquid processing device 160 and the drying device 170. The deliverer 140 includes a holder 141, an irradiator 142, an airflow former 143, and a humidity sensor 144.

The holder 141 includes a housing 141a and a holding claw 141b. The housing 141a forms an accommodation space in which a plurality of substrates W is accommodated in multiple stages. A first opening 141c is provided in an upper portion of the housing 141a. The first opening 141c functions as an inlet through which a clean gas discharged by the airflow former 143 to be described later) is introduced into the housing 141a. A second opening 141d is provided in a lower portion of the housing 141a. The second opening 141d functions as an outlet through which the clean gas out of the housing 141a is discharged. The holding claw 141b holds an outer periphery of the substrate W from below in the interior of the housing 141a. A form in which the holder 141 holds the substrate W is not limited to that shown in FIG. 4. For example, the holder 141 may have a groove portion (not shown) formed in an inner wall of the housing 141a, instead of the holding claw 141b, and may be configured to hold the outer periphery of the substrate W from below using the groove portion.

The irradiator 142 irradiates the substrate W held by the holder 141 with infrared light. The infrared light is absorbed by moisture or the like. Thus, vapor inside the fine pattern formed on the processing surface of the substrate W is heated by the infrared light so that dew condensation inside the fine pattern is suppressed. This makes it possible to suppress generation of the dew condensation due to capillary condensation caused by the vapor inside the fine pattern formed on the processing surface of the substrate W during a period from when drying processing is performed until the substrate W is accommodated in the carrier C. As a result, the collapse of the fine pattern due to a surface tension of water droplets may be reduced. Further, the infrared light passes through the substrate W such as a semiconductor wafer. Thus, the substrate W is not heated, and a temperature of the substrate W does not rise. In this way, by irradiating the substrate W held by the holder 141 with the infrared light, the irradiator 142 may suppress the dew condensation inside the fine pattern formed on the processing surface of the substrate W without increasing the temperature of the substrate W. Further, as shown in FIG. 5, even when the plurality of substrates W is accommodated in multiple stages inside the housing 141a, the infrared light irradiated by the irradiator 142 is not absorbed by the substrates W and reaches the upperlying substrates W. Therefore, the dew condensation inside the fine pattern formed on the processing surface of the substrate W may be suppressed with respect to all substrates W in the interior of the housing 141a without raising the temperature of the substrates W.

A wavelength of the infrared light may be 1.2 μm or more and 10.0 μm or less. In this case, the infrared light is easily absorbed by moisture.

The irradiator 142 may be provided below the housing 141a. The irradiator 142 may be a source of particles. As will be described later, a downflow directed downward from above is formed in the interior of the housing 141a. For this reason, when the irradiator 142 is provided below the housing 141a, even if the particles are generated from the irradiator 142, they do not move toward the housing 141a, but rather travel downward along the downflow. This makes it possible to suppress the particles originating from the irradiator 142 from adhering to the substrate W. When the processing surface of the substrate W is an upper surface of the substrate W, the irradiator 142 does not face the processing surface of the substrate W, but the infrared light passes through the substrate W as described above. Therefore, the vapor inside the fine pattern formed on the processing surface of the substrate W may be heated by the infrared light irradiated by the irradiator 142 even without inverting the substrate W. In this way, the irradiator 142 may irradiate the substrate W held by the holder 141 with the infrared light from a surface opposite to the processing surface of the substrate W. A position at which the irradiator 142 is provided is not limited to the lower side of the housing 141a. For example, the irradiator 142 may be provided in the interior of the housing 141a, for instance, on an inner surface of the housing 141a.

The airflow former 143 is provided above the housing 141a. The airflow former 143 is provided, for example, to cover the entire housing 141a from above. The airflow former 143 forms an airflow in an area including the interior of the housing 141a. The airflow former 143 discharges a clean gas into the housing 141a in a downward direction. The discharged clean gas forms an airflow that flows into the housing 141a from the first opening 141c and is discharged from the second opening 141d. That is, the airflow former 143 forms the airflow (the downflow) directed downward from above in the interior of the housing 141a. The clean gas may be clean air containing air in an interior of a clean room that has been filtered by a filter. The airflow former 143 is, for example, a fan filter unit (FFU).

The humidity sensor 144 detects humidity at the second opening 141d of the housing 141a. The humidity sensor 144 transmits data about the detected humidity to the control circuit 190. The control circuit 190 may adjust an output of the infrared light irradiated by the irradiator 142 based on the humidity-related data received from the humidity sensor 144. For example, the control circuit 190 may stop the irradiation of the infrared light by the irradiator 142 when the humidity-related data received from the humidity sensor 144 falls below a threshold value.

The control circuit 190 may adjust the output of the infrared light irradiated by the irradiator 142 based on the positions and number of the substrates W held by the holder 141. Amounts of heat applied to the vapor inside the fine pattern formed on the processing surface of the substrate W are different from each other according to a distance between the irradiator 142 and the substrate W. Further, although the infrared light passes through the substrate W, energy is attenuated by the substrate W. That is, a first substrate W held by the holder 141 and a second substrate W loaded subsequently receive different amounts of heat from the irradiator 142. For this reason, by adjusting the output of the infrared light irradiated by the irradiator 142 based on the positions and number of the substrates W held by the holder 141, a variation in the amount of heat applied to the vapor inside the fine pattern formed on the processing surface of each substrate W held by the holder 141 may be reduced. For example, the control circuit 190 performs control such that the substrate W first loaded into the holder 141 is held at the uppermost stage (a first stage) of the holder 141, and the subsequently-loaded substrate W is held at a second stage and that the output of the infrared light irradiated by the irradiator 142 is reduced. The control circuit 190 may also perform the same control with respect to the subsequently-loaded substrates W. In this case, the variation in the amount of heat applied to the vapor inside the fine pattern formed on the processing surface of each substrate W may be reduced.

### Substrate Processing Method

Next, an example of a substrate processing method performed by the substrate processing apparatus 100 shown in FIG. 1 will be described.

First, the first transfer mechanism 130 takes the substrate W out of the carrier C and transfers the same to the deliverer 140. Subsequently, the second transfer mechanism 180 takes the substrate W out of the deliverer 140 and transfers the same to the liquid processing device 160. Next, the liquid processing device 160 performs the liquid processing on the substrate W. Then, the second transfer mechanism 180 takes the substrate W out of the liquid processing device 160 and transfers the same to the drying device 170. Thereafter, the drying device 170 performs the drying processing on the substrate W.

Next, the second transfer mechanism 180 takes the substrate W out of the drying device 170 and transfers the same to the deliverer 140. In the deliverer 140, the irradiator 142 irradiates the substrate W held by the holder 141 with the infrared light. Thus, the vapor inside the fine pattern formed on the processing surface of the substrate W is heated by the infrared light, and the dew condensation inside the fine pattern is suppressed. This makes it possible to suppress the generation of the dew condensation due to the capillary condensation caused by the vapor inside the fine pattern formed on the processing surface of the substrate W during a period from when the drying processing is performed until the substrate W is accommodated in the carrier C. This makes it possible to reduce the collapse of the fine pattern due to the surface tension of water droplets. In the deliverer 140, the airflow former 143 may form the airflow in the area including the interior of the housing 141a.

Next, the first transfer mechanism 130 takes the substrate W out of the deliverer 140 and transfers the same to the carrier C. Humidity inside the carrier C may be reduced by the air conditioner. In this case, while the substrate W is being accommodated in the carrier C, the absorption of the moisture in the substrate W (especially the fine pattern) after the drying processing is reduced, which makes it possible to suppress the collapse of the fine pattern. The carrier C is unloaded from the stage 110 while accommodating the plurality of substrates W.

In this way, the substrate processing method performed by the substrate processing apparatus 100 is terminated.

### Second Embodiment

### Substrate Processing Apparatus

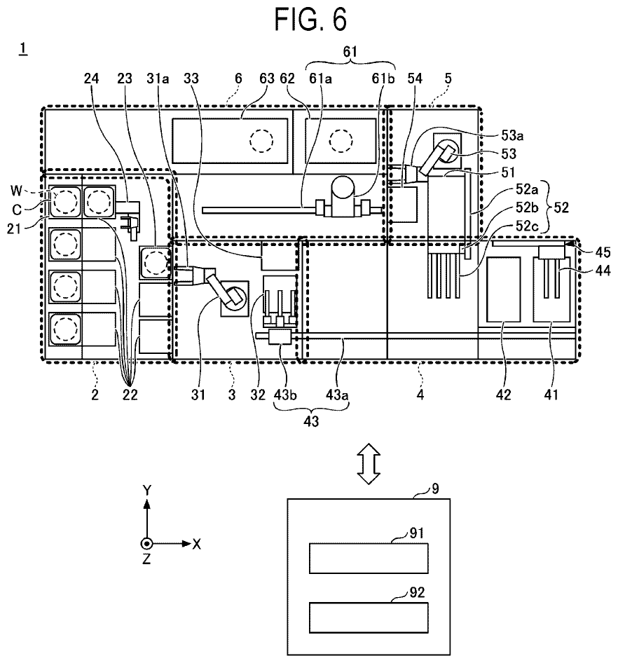

A substrate processing apparatus 1 according to a second embodiment will now be described with reference to FIG. 6. FIG. 6 is a schematic plan view illustrating the substrate processing apparatus 1 according to the second embodiment.

The substrate processing apparatus 1 is configured as an apparatus which is capable of performing both batch processing on a lot L including a plurality of substrates W and single-substrate processing on the substrates W in the lot L one by one. The substrate processing apparatus 1 includes a loading/unloading part 2, a first interface part 3, a batch processor 4, a second interface part 5, a single-substrate processor 6, and a control circuit 9.

The loading/unloading part 2 serves both as a loading part and an unloading part. This reduces a size of the substrate processing apparatus 1. The loading/unloading part 2 includes a load port 21, a stocker 22, a loader 23, and a carrier transfer device 24.

The load port 21 is arranged on a negative side of the loading/unloading part 2 in the X axis. A plurality (for example, four) of load ports 21 is arranged along the Y axis. The number of the load ports 21 is not particularly limited. Carriers C are placed on the load ports 21. Each carrier C accommodates a plurality (for example, 25) of substrates W and is loaded and unloaded via the load port 21. The substrates W are held horizontally inside the carrier C and held at a second pitch P2 (P2=N×P1), which is N times a first pitch P1, along the Z axis. N is a natural number equal to or greater than 2. N is 2 in the present embodiment but may be 3 or greater.

A plurality (for example, four) of stockers 22 is arranged along the Y axis at the center of the loading/unloading part 2 in the X axis. The plurality (for example, two) of stockers 22 is arranged to be adjacent to the first interface part 3 along the Y axis on a positive side of the loading/unloading part 2 in the X axis. The stockers 22 may be arranged in multiple stages along the Z axis. The stockers 22 temporarily store the carrier C accommodating the substrates W before cleaning processing, the carrier C, the interior of which is empty after the substrates W are taken out of the carrier C, and the like. The number of the stockers 22 is not particularly limited.

The loader 23 is provided to be adjacent to the first interface part 3. The loader 23 is arranged on the positive side of the loading/unloading part 2 in the X axis. The carriers C are placed on the loader 23. The loader 23 is provided with a cover-body opening/closing mechanism (not shown) for opening and closing a cover body of the carrier C. A plurality of loaders 23 may be provided. The loaders 23 may be arranged in multiple stages along the Z axis.

The carrier transfer device 24 transfers the carriers C between the load port 21, the stocker 22, and the loader 23. The carrier transfer device 24 is, for example, an articulated transfer robot.

The first interface part 3 is arranged on the positive side of the loading/unloading part 2 in the X axis. The first interface part 3 transfers the substrates W between the loading/unloading part 2, the batch processor 4, and the single-substrate processor 6. The first interface part 3 includes a substrate transfer device 31, a lot former 32, and a first deliverer 33.

The substrate transfer device 31 transfers the substrates W between the carrier C placed on the loader 23, the lot former 32, and the first deliverer 33. The substrate transfer device 31 is constituted with a multi-axis (for example, six axes) arm robot and includes a substrate holding arm 31a at a tip end thereof. The substrate holding arm 31a includes a plurality of holding claws (not shown) capable of holding the plurality (for example, 25) of substrates W. The substrate holding arm 31a may take any posture at a certain position in a three-dimensional space while holding the substrates W with the holding claws.

The lot former 32 is arranged on the positive side of the first interface part 3 in the X axis. The lot former 32 holds the plurality of substrates W at the first pitch P1 (P1=P2/N) and forms the lot L.

The first deliverer 33 is provided to be adjacent to the single-substrate processor 6. The first deliverer 33 is arranged on the positive side of the first interface part 3 in the Y axis. The first deliverer 33 receives the substrates W from a fourth transfer device 61 and temporarily stores the substrates W until the substrates W are delivered to the loading/unloading part 2. The first deliverer 33 may have the same configuration as that of the deliverer 140 described above. In this case, it possible to suppress the dew condensation from being generated due to the capillary condensation caused by the vapor inside the fine pattern formed on the processing surface of the substrate W during a period from when the drying processing is performed until the substrate W is accommodated in the carrier C. Accordingly, it is possible to reduce the collapse of the fine pattern due to the surface tension of water droplets.

The batch processor 4 is arranged on the positive side of the first interface part 3 in the X axis. The loading/unloading part 2, the first interface part 3, and the batch processor 4 are arranged in this order from the negative side of the X axis toward the positive side of the X axis. The batch processor 4 processes the lot L including the plurality (for example, 50 or 100) of substrates W at the first pitch P1 in a batch manner. One lot L is composed of the substrates W of, for example, M carriers C. M is a natural number equal to or greater than 2. M may be the same natural number as N or may be a natural number different from N. The batch processor 4 includes a chemical liquid bath 41, a rinse liquid bath 42, a first transfer device 43, a processing tool 44, and a drive device 45.

The chemical liquid bath 41 and the rinse liquid bath 42 are arranged along the X axis. For example, the chemical liquid bath 41 and the rinse liquid bath 42 are arranged in this order from the positive side of the X axis toward the negative side of the X axis. The chemical liquid bath 41 and the rinse liquid bath 42 are collectively referred to as a processing bath. The number of chemical liquid baths 41 and rinse liquid baths 42 is not limited to those shown in FIG. 1. For example, the chemical liquid bath 41 and the rinse liquid bath 42 are provided in one set in FIG. 1 but may be provided in a plurality of sets.

The chemical liquid bath 41 stores a chemical liquid in which the lot L is immersed. The chemical liquid is, for example, an aqueous phosphoric acid solution (H₃PO₄). The aqueous phosphoric acid solution selectively etches and removes a silicon nitride film from among a silicon oxide film and the silicon nitride film. The chemical liquid is not limited to the aqueous phosphoric acid solution. The chemical liquid may be dilute hydrofluoric acid (DHF), a mixture of hydrofluoric acid and ammonium fluoride (BHF), dilute sulfuric acid, a mixture of sulfuric acid, hydrogen peroxide, and water (SPM), a mixture of ammonia, hydrogen peroxide, and water (SC1), a mixture of hydrochloric acid, hydrogen peroxide, and water (SC2), a mixture of tetramethylammonium hydroxide and water (TMAH), a plating liquid, or the like. The chemical liquid may be used for stripping processing or plating processing. The number of chemical liquids is not particularly limited and may be plural.

The rinse liquid bath 42 stores a first rinse liquid in which the lot L is immersed. The first rinse liquid is pure water that removes the chemical liquid from the substrate W and is, for example, deionized water.

The first transfer device 43 includes a guide rail 43a and a first transfer arm 43b. The guide rail 43a is arranged on the negative side of the Y axis relative to the processing bath. The guide rail 43a extends along the X axis from the first interface part 3 to the batch processor 4. The first transfer arm 43b moves along the guide rail 43a. The first transfer arm 43b may move along the Z axis or rotate around the Z axis. The first transfer arm 43b transfers the lot L between the first interface part 3 and the batch processor 4 in a batch manner.

The processing tool 44 receives and holds the lot L from the first transfer arm 43b. The processing tool 44 holds the plurality of substrates W at the first pitch P1 along the Y axis and holds each of the plurality of substrates W vertically.

The drive device 45 moves the processing tool 44 along X axis and the Z axis. The processing tool 44 immerses the lot L in the chemical liquid stored in the chemical liquid bath 41, immerses the lot L in the first rinse liquid stored in the rinse liquid bath 42, and then delivers the lot L to the first transfer device 43.

The number of units of the processing tool 44 and the drive device 45 is one in the present embodiment but may be plural. In the latter case, one unit immerses the lot L in the chemical liquid stored in the chemical liquid bath 41, and another unit immerses the lot L in the first rinse liquid stored in the rinse liquid bath 42. In this case, the drive device 45 only needs to move the processing tool 44 along the Z axis and does not need to move the processing tool 44 along the X axis.

The second interface part 5 is arranged on a positive side of the batch processor 4 in the Y axis. The second interface part 5 transfers the substrates W between the batch processor 4 and the single-substrate processor 6. The second interface part 5 includes an immersion bath 51, a second transfer device 52, a third transfer device 53, and a second deliverer 54.

The immersion bath 51 is arranged outside a movement range of the first transfer arm 43b. For example, the immersion bath 51 is arranged at a position shifted on the positive side of the Y axis with respect to the processing bath. The immersion bath 51 stores a second rinse liquid in which the lot L is immersed. The second rinse liquid is, for example, deionized water. The substrates W are held in the second rinse liquid until the substrates W are lifted out of the second rinse liquid by the third transfer device 53. Since the substrates W are present below a liquid level of the second rinse liquid, a surface tension of the second rinse liquid does not act on the substrates W, which makes it possible to prevent the fine pattern of the substrates W from collapsing.

The second transfer device 52 includes a Y-axis drive device 52a, a Z-axis drive device 52b, and a second transfer arm 52c.

The Y-axis drive device 52a is arranged on the positive side of the second interface part 5 in the X axis. The Y-axis drive device 52a extends along the Y axis from the second interface part 5 to the batch processor 4. The Y-axis drive device 52a moves the Z-axis drive device 52b and the second transfer arm 52c along the Y axis. The Y-axis drive device 52a may include a ball screw.

The Z-axis drive device 52b is movably attached to the Y-axis drive device 52a. The Z-axis drive device 52b moves the second transfer arm 52c along the Z axis. The Z-axis drive device 52b may include a ball screw.

The second transfer arm 52c is movably attached to the Z-axis drive device 52b. The second transfer arm 52c receives and holds the lot L from the first transfer arm 43b. The second transfer arm 52c holds the plurality of substrates W at the first pitch P1 along the Y axis and holds each of the plurality of substrates W vertically. The second transfer arm 52c moves along the Y axis and the Z axis by the Y-axis drive device 52a and the Z-axis drive device 52b. The second transfer arm 52c is configured to be movable between multiple positions including a delivery position, an immersion position, and a standby position.

The delivery position is a position at which the lot L is delivered between the first transfer arm 43b and the second transfer arm 52c. The delivery position is a position on the negative side of the Y axis and also on the positive side of the Z axis.

The immersion position is a position at which the lot L is immersed in the immersion bath 51. The immersion position is a position on the positive side of the Y axis and also on the negative side of the Z axis relative to the delivery position.

The standby position is a position at which the second transfer arm 52c waits when the lot L is not being delivered or is not being immersed in the immersion bath 51. The standby position is directly below the delivery position (the negative side of the Z axis) and is a position that does not interfere with the movement of the first transfer arm 43b. In this case, since the second transfer arm 52c may move to the delivery position only by moving upward (the positive side of the Z axis), throughput is improved. The standby position may be the same position as the immersion position. In this case, it is possible to prevent particles, which may be generated with the operation of the first transfer device 43, from adhering to the second transfer arm 52c. The standby position may be a position directly above the immersion position (the positive side of the Z axis). In this way, by setting the standby position to a position different from the delivery position, it is possible to prevent the first transfer arm 43b and the second transfer arm 52c from coming into contact with each other.

The second transfer device 52 moves the second transfer arm 52c to the immersion position or the standby position while the first transfer device 43 is operating. This makes it possible to prevent the first transfer arm 43b and the second transfer arm 52c from coming into contact with each other.

The third transfer device 53 is constituted with a multi-axis (for example, six axes) arm robot and includes a third transfer arm 53a at a tip end thereof. The third transfer arm 53a includes a holding claw (not shown) capable of holding one substrate W. The third transfer arm 53a may take any posture at a certain position in three-dimensional space while holding the substrate W with the holding claw. The third transfer device 53 transfers the substrate W between the second transfer arm 52c located at the immersion position and the second deliverer 54. In this case, since the immersion bath 51 is arranged outside a movement range of the first transfer arm 43b, the first transfer arm 43b and the third transfer arm 53a do not interfere with each other. This makes it possible to independently operate one of the first transfer device 43 and the third transfer device 53 regardless of an operating state of the other. Thus, since the first transfer device 43 and the third transfer device 53 may operate at any timing, the time required to transfer the substrate W may be shortened. As a result, the productivity of the substrate processing apparatus 1 is improved.

The second deliverer 54 is provided to be adjacent to the single-substrate processor 6. The second deliverer 54 is arranged on the negative side of the second interface part 5 in the X axis. The second deliverer 54 receives the substrates W from the third transfer device 53 and temporarily stores the same until the substrates W are delivered to the single-substrate processor 6. The substrates W taken out of the immersion bath 51 are placed on the second deliverer 54. The substrates W placed on the second deliverer 54 are desirably in a state in which, for example, the surfaces of the substrates W are wet with the second rinse liquid. In this case, the surface tension of the second rinse liquid does not act on the substrates W, which makes it possible to suppress the fine pattern on the substrates W from collapsing. The number of second deliverer 54 may be one or plural.

The single-substrate processor 6 is arranged on the negative side of the second interface part 5 in the X axis. The single-substrate processor 6 is arranged on the positive side of the loading/unloading part 2, the first interface part 3, and the batch processor 4 in the Y axis. The single-substrate processor 6 processes the substrates W one by one. The single-substrate processor 6 includes the fourth transfer device 61, a liquid processing device 62, and a drying device 63.

The fourth transfer device 61 includes a guide rail 61a and a fourth transfer arm 61b.

The guide rail 61a is arranged on the negative side of the single-substrate processor 6 in the Y axis. The guide rail 61a extends along the X axis in the single-substrate processor 6.

The fourth transfer arm 61b moves along the guide rail 61a. The fourth transfer arm 61b rotates around the Z axis. The fourth transfer arm 61b transfers the substrates W between the second deliverer 54, the liquid processing device 62, the drying device 63, and the first deliverer 33. The number of fourth transfer arms 61b may be one or plural. In the latter case, the fourth transfer device 61 transfers the plurality (for example, five) of substrates W in a batch manner.

The liquid processing device 62 is arranged on the positive side of the single-substrate processor 6 in the X axis and also on the positive side of the single-substrate processor 6 in the Y axis. The liquid processing device 62 is of a single-substrate type and processes the substrates W one by one with a processing liquid. The liquid processing device 62 is arranged in multiple stages (for example, three stages) along the Z axis. This makes it possible to process simultaneously the plurality of substrates W with the processing liquid. The processing liquid may include a plurality of liquids and may be, for example, pure water, such as deionized water, and a drying liquid having a lower surface tension than the pure water. The drying liquid may be an alcohol such as isopropyl alcohol (IPA).

The drying device 63 is arranged to be adjacent to the liquid processing device 62 on the negative side of the X axis. In this case, an end surface of the single-substrate processor 6 on the positive side of the Y axis may be arranged so as to flush or substantially flush with an end surface of the second interface part 5 on the positive side of the Y axis. This results in almost no dead space, which may reduce the footprint of the substrate processing apparatus 1. In contrast, in a case in which the drying device 63 is arranged to be adjacent to the liquid processing device 62 on the positive side of the Y axis, the end surface of the single-substrate processor 6 on the positive side of the Y axis may protrude farther than the end surface of the second interface part 5 on the positive side of the Y axis, which may generate the dead space. The drying device 63 is of a single-substrate type and dries the substrates W one by one with a supercritical fluid. The drying device 63 is arranged in multiple stages (for example, three stages) along the Z axis. This makes it possible to simultaneously dry the plurality of substrates W.

Both the liquid processing device 62 and the drying device 63 may not be of a single-substrate type, or the liquid processing device 62 may be of a single-substrate type and the drying device 63 may be of a batch type. The drying device 63 may dry the plurality of substrates W with the supercritical fluid in a batch manner. The number of the substrates W processed in the batch manner in the drying device 63 may be equal to or greater than that of the substrates W processed in the batch manner in the liquid processing device 62 but may be less. Devices other than the liquid processing device 62 and the drying device 63 may be arranged in the single-substrate processor 6.

In this embodiment, each substrate W, after undergoing the liquid processing and drying processing described above, is accommodated in the carrier C, humidity of which has been lowered by the air conditioner (not shown) for the carrier C. As a result, the absorption of moisture in the substrate W (especially, in the fine pattern) after the drying processing is reduced while the substrate W is accommodated in the carrier C, thus making it possible to suppress the collapse of the fine pattern.

The configuration of the apparatus for maintaining the interior of each carrier C in a low humidity and the method therefor are not particularly limited. For example, a purge device (not shown) that functions as the air conditioner may be installed at the load port 21. The carrier C may be connected to the purge device when the carrier C is placed on the load port 21. In this case, by supplying a low-humidity purge gas (an inert gas such as a nitrogen gas) from the purge device into the carrier C, the interior of the carrier C is purged by the low-humidity purge gas. Thus, the interior of the carrier C may be adjusted to have a low-humidity atmosphere.

The control circuit 9 is, for example, a computer. The control circuit 9 includes a calculator 91 such as a central processing unit (CPU) and a storage 92 such as a memory. The storage 92 stores programs for controlling various processes executed in the substrate processing apparatus 1. The control circuit 9 controls the operation of the substrate processing apparatus 1 by causing the calculator 91 to execute the programs stored in the storage 92. The programs may be stored in a non-transitory computer-readable storage medium (device) such as, for example, a hard disk, a compact disc, a magneto-optical disc, a memory card, or a non-volatile memory, and may be installed on a computer from the storage medium

The control circuit 9 includes one or more electronic circuits such as the CPU, a field programmable gate array (FPGA), or an application specific integrated circuit (ASIC). The control circuit 9 executes various control operations described in this specification by executing instruction codes stored in the memory or by designing a circuit for a specific purpose.

In the substrate processing apparatus 1, the substrates W are transferred in the order from the loading/unloading part 2 to the first interface part 3, the batch processor 4, the second interface part 5, and the single-substrate processor 6 and then return to the loading/unloading part 2.

### Substrate Processing Method

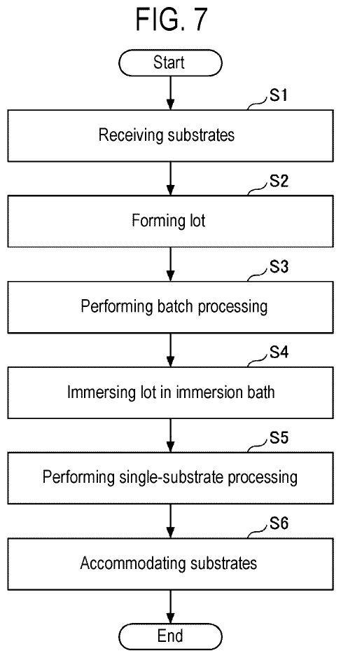

An example of the substrate processing method performed by the substrate processing apparatus 1 shown in FIG. 6 will now be described with reference to FIG. 7. FIG. 7 is a flowchart illustrating the substrate processing method according to the second embodiment. Processing shown in FIG. 7 is performed under the control of the control circuit 9.

First, the carrier C is loaded into the loading/unloading part 2 and placed on the load port 21 in a state in which the carrier C accommodates the plurality of substrates W. The substrates W are held horizontally in the interior of the carrier C and held at the second pitch P2 (P2=N×P1) in the vertical direction. N is a natural number equal to or greater than 2 and N is 2 in the present embodiment but may be 3 or greater.

Next, the carrier transfer apparatus 24 transfers the carrier C from the load port 21 to the loader 23. The cover body of the carrier C transferred to the loader 23 is opened by the cover-body opening/closing mechanism.

Next, the substrate transfer device 31 receives the substrates W accommodated in the carrier C (Step S1 in FIG. 7) and transfers the substrates W to the lot former 32.

Subsequently, the lot former 32 holds the plurality of substrates W at the first pitch P1 (P1=P2/N) to form the lot L. One lot L is composed of the substrates W of, for example, M carriers C. Since the pitch of the substrate W is narrowed from the second pitch P2 to the first pitch P1, the number of the substrates W processed in the batch manner may be increased.

Next, the first transfer device 43 receives the lot L from the lot former 32 and transfers the same to the processing tool 44.

Next, the processing tool 44 descends from above the chemical liquid bath 41, immerses the lot L in the chemical liquid, and performs chemical processing (Step S3 in FIG. 7). Thereafter, the processing tool 44 ascends to lift the lot L out of the chemical liquid and then moves in the horizontal direction (the negative side of the X axis) toward a position above the rinse liquid bath 42.

Subsequently, the processing tool 44 descends from above the rinse liquid bath 42, immerses the lot L in the first rinse liquid, and performs rinse liquid processing (Step S3 in FIG. 7). Thereafter, the processing tool 44 ascends to lift the lot L out of the first rinse liquid. Next, the first transfer apparatus 43 receives the lot L from the processing tool 44 and transfers the same to the second transfer device 52.

Subsequently, the second transfer arm 52c of the second transfer device 52 moves in the horizontal direction (the positive side of the Y axis) and descends from above the immersion bath 51, thereby immersing the lot L in the second rinse liquid (Step S4 in FIG. 7). The plurality of substrates W in the lot L is held in the second rinse liquid until the substrates W are lifted out of the second rinse liquid by the third transfer device 53. Since the substrates W are present below a liquid level of the second rinse liquid, the surface tension of the second rinse liquid does not act on the substrates W, which makes it possible to prevent the fine pattern on the substrates W from collapsing.

Next, the third transfer device 53 transfers the substrates W of the lot L, which are held in the second rinse liquid by the second transfer arm 52c, to the second deliverer 54. For example, the third transfer device 53 transfers the substrates W to the second deliverer 54.

Subsequently, the fourth transfer device 61 receives the substrates W from the second deliverer 54 and transfers the same to the liquid processing device 62.

Next, the liquid processing device 62 processes the substrates W one by one with a liquid (Step S5 in FIG. 7). The number of liquids may be plural and the liquids may be, for example, pure water such as deionized water and a drying liquid having a lower surface tension than the pure water. The drying liquid may be an alcohol such as IPA. The liquid processing device 62 sequentially supplies the pure water and the drying liquid to the upper surface of the substrate W to form a liquid film of the drying liquid.

Next, the fourth transfer device 61 receives the substrates W from the liquid processing device 62 and holds the same horizontally with the liquid film of the drying liquid facing upward. The fourth transfer device 61 transfers the substrates W from the liquid processing device 62 to the drying device 63.

Next, the drying device 63 dries the substrates W one by one with a supercritical fluid (Step S5 in FIG. 7). The drying liquid may be replaced with the supercritical fluid, which makes it possible to suppress the fine pattern on the substrates W from collapsing due to the surface tension of the drying liquid. Since the supercritical fluid requires a pressure-resistant container, the substrates W are processed by the single-substrate processing rather than the batch processing in order to reduce the size of the pressure-resistant container.

The drying device 63 is of a single-substrate type but, as described above, may be of a batch type. The batch-type drying device 63 dries the plurality of substrates W, on which the liquid film has been formed, with the supercritical fluid in the batch manner. The single-substrate-type drying device 63 includes one transfer arm for holding the substrates W, whereas the batch-type drying device 63 includes a plurality of transfer arms.

In the present embodiment, the drying device 63 dries the substrates W with the supercritical fluid. However, such a drying method is not particularly limited. The drying method may be any method as long as it can suppress the collapse of the fine pattern on the substrates W, and may be, for example, spin drying, scan drying, water-repellent drying, or the like. The spin drying is a method in which the liquid processing device 62 rotates the substrate W to remove the drying liquid from the upper surface of the substrate W by shaking the drying liquid off the substrate W by virtue of a centrifugal force. The scan drying includes shaking the liquid film off the substrate W by virtue of the centrifugal force by rotating the substrate W while a supply position of the drying liquid is moved from the center of the substrate W to an outer periphery of the substrate W. The scan drying may include moving a supply position of a drying gas such as a nitrogen gas, from the center of the substrate W toward the outer periphery of the substrate W so as to follow the supply position of the drying liquid.

Subsequently, the fourth transfer device 61 receives the substrates W from the drying device 63 and transfers the same to the first deliverer 33. The first deliverer 33 may have the same configuration as that of the deliverer 140. That is, the first deliverer 33 may include the holder 141, the irradiator 142, the airflow former 143, and the humidity sensor 144. Next, the irradiator 142 irradiates the substrates W held by the holder 141 with the infrared light. Thus, the vapor inside the fine pattern formed on the processing surface of the substrate W is heated by the infrared light, so that the dew condensation in the fine pattern is suppressed. This makes it possible to suppress the generation of the dew condensation due to the capillary condensation caused by the vapor inside the fine pattern formed on the processing surface of the substrate W during a period from when the drying processing is performed until the substrate W is accommodated in the carrier C. Thia makes it possible to suppress the fine pattern from collapsing due to the surface tension of water droplets. In the first deliverer 33, the airflow former 143 may form the airflow in the area including the interior of the housing 141a.

Subsequently, the substrate transfer device 31 receives the substrates W from the first deliverer 33 and accommodates the same in the carrier C (Step S6 in FIG. 7). The humidity in the interior of the carrier C may be reduced by the air conditioner. In this case, while the substrates W are being accommodated in the carrier C, the absorption of moisture in the substrates W (especially, the fine pattern) after the drying processing is reduced, which makes it possible to suppress the fine pattern from collapsing. The carrier C is unloaded from the loading/unloading part 2 while accommodating the plurality of substrates W.

In this way, the substrate processing method performed by the substrate processing apparatus 1 is terminated.

According to the present disclosure in some embodiments, it is possible to reduce a collapse of a fine pattern.

It should be noted that the embodiments disclosed herein are exemplary in all aspects and are not restrictive. The above-described embodiments may be omitted, replaced, or modified in various forms without departing from the scope and spirit of the appended claims.

What is claimed is:

1. A substrate processing apparatus, comprising:
a drying device configured to dry a processing surface of at least one substrate;
a holder configured to hold the at least one substrate dried by the drying device; and
an irradiator configured to irradiate the at least one substrate held by the holder with infrared light.

2. The substrate processing apparatus of claim 1, further comprising: an airflow former provided above the holder and configured to form an airflow in an area including the holder,
wherein the irradiator is provided below the holder.

3. The substrate processing apparatus of claim 1, wherein the irradiator irradiates the at least one substrate held by the holder with the infrared light from a surface opposite to the processing surface of the at least one substrate.

4. A substrate processing apparatus of claim 2, wherein the holder includes a housing configured to accommodate the at least one substrate in an interior of the holder,
wherein a first opening is formed in an upper portion of the housing,
wherein a second opening is formed in a lower portion of the housing, and
wherein the airflow former forms the airflow which flows into the housing from the first opening and is discharged from the first opening.

5. The substrate processing apparatus of claim 4, further comprising: a humidity sensor configured to detect humidity at the second opening of the housing.

6. The substrate processing apparatus of claim 1, further comprising:
a liquid processing device configured to perform a process of forming a liquid film on the processing surface of the at least one substrate; and
a transferor configured to transfer the at least one substrate processed by the liquid processing device to the drying device,
wherein the drying device dries the at least one substrate by replacing the liquid film formed on the processing surface of the at least one substrate with a supercritical fluid.

7. The substrate processing apparatus of claim 1, wherein the at least one substrate includes a plurality of substrates,
the substrate processing apparatus further comprises:
a batch processor configured to collectively process a lot including the plurality of substrates,
wherein the plurality of substrates processed by the drying device are included in the lot processed by the batch processor.

8. The substrate processing apparatus of claim 1, further comprising:
a carrier configured to accommodate the at least one substrate held by the holder in an interior of the carrier; and
an air conditioner configured to adjust an atmosphere of the interior of the carrier to a low-humidity atmosphere.

9. The substrate processing apparatus of claim 1, further comprising: a control circuit,
wherein the control circuit adjusts an output of the infrared light irradiated by the irradiator based on a position and number of the at least one substrate held by the holder.

10. The substrate processing apparatus of claim 5, further comprising: a control circuit,
wherein the control circuit adjusts an output of the infrared light irradiated by the irradiator based on the humidity detected by the humidity sensor.

11. The substrate processing apparatus of claim 1, wherein a wavelength of the infrared light irradiated by the irradiator is 1.2 μm or more and 10.0 μm or less.

12. A substrate processing method, comprising:
drying a processing surface of a substrate;
holding the substrate by a holder, wherein the processing surface of the substrate has been dried; and
irradiating the substrate held by the holder with infrared light.
